(19) United States
(12) Patent Application Publication
(10) Pub. No.: US 2024/0404868 A1
(43) Pub. Date: Dec. 5, 2024

(54) STANDING WAFER HOLDER

(71) Applicant: HANGZHOU SIZONE ELECTRONIC TECHNOLOGY INC., Zhejiang (CN)

(72) Inventor: Zhengting ZHU, Zhejiang (CN)

(73) Assignee: HANGZHOU SIZONE ELECTRONIC TECHNOLOGY INC., Zhejiang (CN)

(21) Appl. No.: 18/716,132

(22) PCT Filed: Dec. 30, 2022
(86) PCT No.: PCT/CN2022/144006

§ 371 Date: Jun. 3, 2024

(30) Foreign Application Priority Data
Dec. 15, 2021 (CN) 202111533401.X

(51) Int. Cl. H01L 21/687; H01L 21/673

(52) U.S. Cl. CPC H01L 21/68785; H01L 21/673; H01L 21/68735

(57) ABSTRACT

Disclosed is a standing wafer holder comprising at least one base unit which comprises first and second wafer seats. The first wafer seat top is provided with a first arc-shaped concave surface, a first acting surface is formed on a side, facing the second wafer seat, of the first wafer seat and corresponds to an area where the first arc-shaped concave surface is located, and the first acting surface is shaped like a left half of Y. The second wafer seat top is provided with a second arc-shaped concave surface, a second acting surface is formed on a side, facing the first wafer seat, of the second wafer seat and corresponds to an area where the second arc-shaped concave surface is located, and the second acting surface is shaped like a right half of Y. The first and second acting surfaces work together to support a wafer vertically.

### TECHNICAL FIELD

The invention belongs to the field of fabrication of semiconductor integrated circuit chips, and particularly relates to a standing wafer holder.

### BACKGROUND OF RELATED ART

Chemical Mechanical Planarization (CMP) is one process of the integrated circuit technology, the requirement for which will become higher with the development of the technology. CMP equipment typically comprises a semiconductor Equipment Front-End Module (EFEM), a cleaning unit, a polishing unit and a transfer module. The EFEM mainly comprises a cassette for storing wafers, a robot arm for transferring wafers, and an air purification system. The cleaning unit mainly comprises a varied number of megasonic cleaning components, roller brush cleaning components, drying components and devices for transferring wafers between the components. The polishing unit mainly comprises a polishing platen, a polishing head, a polishing liquid supply system and a polishing pad conditioner. The transfer module comprises a series of robot arms or mobile platforms for transferring wafers to be polished from the EFEM to the polishing unit and transferring polished wafers from the polishing unit to the cleaning unit.

The presence of notches (flats), which are as wide as 57.5 mm, of 6-inch wafers easily leads to instable placement of the wafers in the vertical direction and even causes inclination or skewing of the wafers, affecting subsequent wafer transfer.

### SUMMARY OF THE INVENTION

To overcome the defects in the prior art, the invention provides a standing wafer holder which can stably support wafers without being affected by notches.

The technical solution adopted by the invention is as follows: a standing wafer holder comprises:
at least one base unit;
the base unit comprises a wafer seat and a second wafer seat;
a top of the first wafer seat is provided with a first arc-shaped concave surface, a first acting surface is formed on a side, facing the second wafer seat, of the first wafer seat and corresponds to an area where the first arc-shaped concave surface is located, and the first acting surface is shaped like a left half of Y;
a top of the second wafer seat is provided with a second arc-shaped concave surface, a second acting surface is formed on a side, facing the first wafer seat, of the second wafer seat and corresponds to an area where the second arc-shaped concave surface is located, and the second acting surface is shaped like a right half of Y;
the first acting surface and the second acting surface work together to support a wafer vertically.

In the invention, the first arc-shaped concave surface is arranged at the top of the first wafer seat, the second arc-shaped concave surface is arranged at the top of the second wafer seat, the first arc-shaped concave surface and the second arc-shaped concave surface are continuous surfaces or discontinuous surface, and the first acting surface and the second acting surface corresponding to the first arc-shaped concave surface and the second arc-shaped concave surface work together to firmly support the wafer, such that the accuracy of the wafer fixing position is high, and skewing of the wafer is avoided, thus facilitating subsequent wafer transfer; the wafer will not shake even in the presence of a large notch, and the position of the notch does not need to accurately located and controlled; and the wafer is supported vertically, such that the problem of large space caused by horizontal placement of the wafer is solved, the space occupied by the base unit is reduced, the space utilization is high, and a robot arm can more easily place the wafer into or take the wafer out of a cleaning tank, in which wafers are placed vertically, of a subsequent cleaning module.

Further, the first acting surface is in line contact with the wafer and the second acting surface is in line contact with the wafer to support the wafer vertically;
or, the first acting surface is in line contact with the wafer and the second acting surface is in surface contact with the wafer to support the wafer vertically;
or, the first acting surface is in surface contact with the wafer and the second acting surface is in surface contact with the wafer to support the wafer vertically.

In the case where the first acting surface and the second acting surface are respectively in line contact with the wafer, the contact area is small, and the influence on the performance of the wafer is minimized; in the case where the first acting surface is in line contact with the wafer and the second acting surface is in surface contact with the wafer, the performance of the front side of the wafer will not be affected; and in the case where the first acting surface and the second acting surface are respectively in surface contact with the wafer, the wafer can be supported more firmly.

Further, the first acting surface comprises a first inclined surface and a first vertical surface, and the second acting surface comprises a second inclined surface and a second vertical surface; and the first vertical surface and the second vertical surface are matched and in contact with each other, and the first inclined surface and the second inclined surface are in line contact with the wafer. The first inclined surface and the second inclined surface form a V-shaped to allow the wafer to be inserted therein easily; and the two inclined surfaces are in line contact with the wafer, such that the contact area is small.

Further, the first acting surface comprises a first inclined surface and a first vertical surface, and the second acting surface comprises a second inclined surface and a second vertical surface; the first vertical surface and the second vertical surface are vertically mismatched and in contact with each other; the first inclined surface is in line contact with the wafer, and the second vertical surface mismatched with the first vertical surface is in surface contact with the wafer; or, the second inclined surface is in line contact with the wafer, and the first vertical surface mismatched with the second vertical surface is in surface contact with the wafer. In this way, the wafer can be supported firmly and will not skew even in a case where a notch of the wafer faces downwards.

Further, the first acting surface comprises a first inclined surface and a first vertical surface, and the second acting surface comprises a second inclined surface and a second vertical surface; and the first vertical surface and the second vertical surface are respectively in contact with outer edges of two sides of the wafer.

Further, a support surface perpendicular to the first vertical surface or the second vertical surface is formed at a bottom of the first vertical surface or at a bottom of the second vertical surface, a step surface is formed at the bottom of the second vertical surface or at the bottom of the first vertical surface, the step surface is erected on the support surface and is horizontally movable along the support surface to adjust a distance between the first vertical surface and the second vertical surface, and the distance is 0.5-2 mm. The distance between the first vertical surface and the second vertical surface can be adjusted to adapt to wafers of different specifications, such that the using flexibility is high; and the distance between the first vertical surface and the second vertical surface can also be adjusted to adapt to machining errors caused by a thickness tolerance during wafer processing.

Further, a surface contact width of the wafer with the first vertical surface or/and the second vertical surface is h, a radius of the wafer is R, and the ratio of h to R is 0.01-1. In this way, the surface of the wafer will not be scratched, the space is saved, and the wafer can be placed more stably, thus reducing the possibility of wafer breakage.

Further, a central angle of the first arc-shaped concave surface or/and the second arc-shaped concave surface is 30°-180°. In this way, after the wafer is placed in the holder, part of the arc of the wafer is limited, ensuring that the wafer is supported firmly and more stably; and the holder can adapt to 6-inch, 8-inch and 12-inch wafers.

Further, the standing wafer holder comprises multiple base units, and the second wafer seat and the first wafer seat of every two adjacent base units are integrated. Multiple base units can be combined freely, such that the structure is more compact, more wafers can be placed in the holder, the applicability is high, and the application range is wide.

Further, the first wafer seat and the second wafer seat are configured as an integrated structure.

Further, the first arc-shaped concave surface and/or the second arc-shaped concave surface are continuous or discontinuous, and the first acting surface and/or the second acting surface are identical or different in structure.

The invention has the following merits: 1) the wafer is stored vertically, such that the problem of large space caused by horizontal storage of the wafer is solved, and a robot arm can more easily place the wafer into or take the wafer out of a cleaning tank, in which wafers are placed vertically, of a subsequent cleaning module; 2) by means of the design of the first arc-shaped concave surface, the second arc-shaped concave surface, the first acting surface and the second acting surface, part of the arc of the wafer is limited after the wafer is placed in the holder, such that the wafer is more stable; 3) the wafer is in linear or surface contact with the holder to be supported, the wafer with a notch can be firmly fixed even if the notch is in contact with the holder, and the notch of the wafer does not need to face upwards, and the position of the notch does not need to be accurately located and controlled; 4) two wafer seats are arranged to support one wafer, multiple wafer seats can be combined to support multiple wafers, and in case of a small space, two sides of each of multiple wafer seats can be designed to be provided with acting surfaces, such that the structure is more compact: 5) the wafer can be stored firmly and will not move even if part of the arc of the wafer is in contact with the first acting surface and the second acting surface; and 6) the performance of the wafer will not be affected.

### BRIEF DESCRIPTION OF THE DRAWINGS

FIG. 1 is a front view of a base unit according to Embodiment 1 of the invention.

FIG. 2 is a perspective view of the base unit according to Embodiment 1 of the invention.

FIG. 3 is a side view of multiple base units according to Embodiment 1 of the invention.

FIG. 4 is a semi-sectional view along A-A in FIG. 3.

FIG. 5 is an enlarged structural view of part B in FIG. 4.

FIG. 6 is a perspective view of multiple base units according to Embodiment 1 of the invention.

FIG. 7 is a perspective view of a base unit according to Embodiment 2 of the invention.

FIG. 8 is a side view of the base unit according to Embodiment 2 of the invention.

FIG. 9 is a sectional view along C-C in FIG. 8.

FIG. 10 is an enlarged structural view of part D in FIG. 9.

FIG. 11 is a front view according to Embodiment 3 of the invention.

FIG. 12 is a perspective view according to Embodiment 3 of the invention.

FIG. 13 is a side sectional view according to Embodiment 3 of the invention.

FIG. 14 is an enlarged structural view of part E in FIG. 13.

### DETAILED DESCRIPTION OF THE INVENTION

To allow those skilled in the art to gain a better understanding of the technical solutions of the invention, the technical solutions of the embodiments of the invention will be clearly and entirely described below in conjunction with accompanying drawings of the embodiments. Obviously, the embodiments in the following description are merely illustrative ones, and are not all possible ones of the invention. All other embodiments obtained by those ordinarily skilled in the art based on the following ones without creative labor should also fall within the protection scope of the invention.

### Embodiment 1

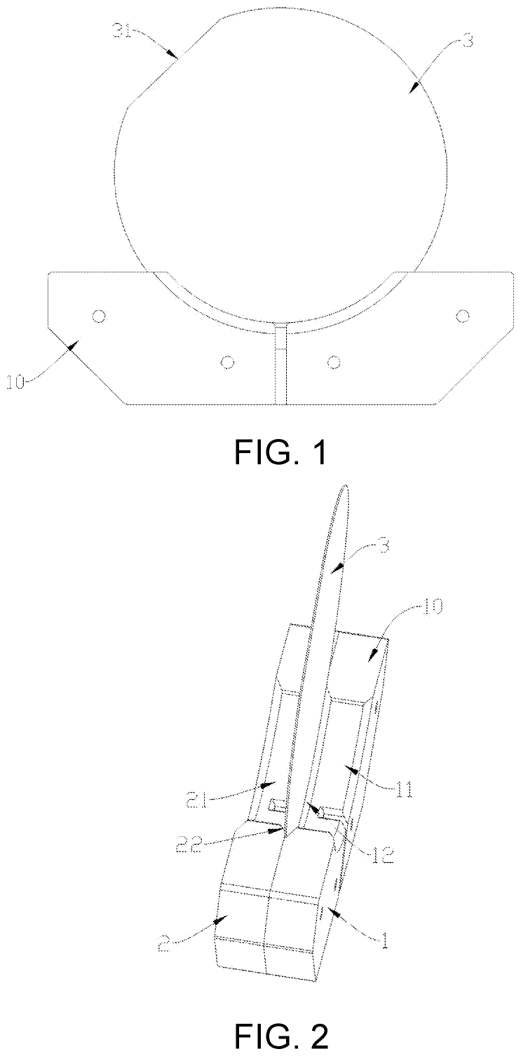

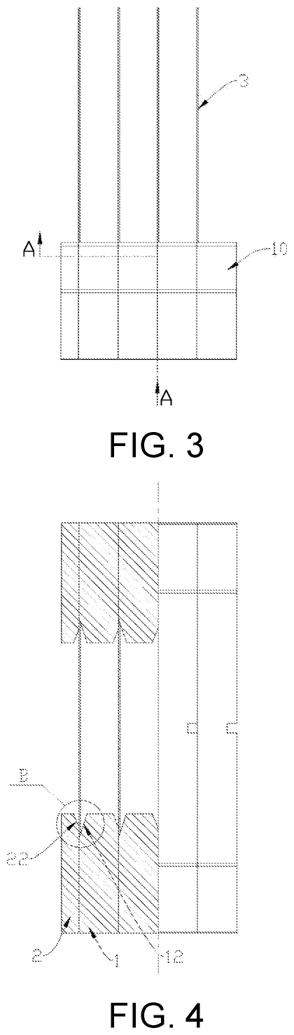

As shown in FIG. 1-FIG. 5, a standing wafer holder comprises at least one base unit 10, wherein the base unit 10 comprises a wafer seat 1 and a second wafer seat 2.

The top of the first wafer seat 1 is provided with a first arc-shaped concave surface 11, a first acting surface 12 is formed on a side, facing the second wafer seat 2, of the first wafer seat 1 and corresponds to an area where the first arc-shaped concave surface 11 is located, and the first acting surface 12 is shaped like a left half of Y. A central angle of the first arc-shaped concave surface 11 is 90°-180°.

The top of the second wafer seat 2 is provided with a second arc-shaped concave surface 21, a second acting surface 22 is formed on a side, facing the first wafer seat 1, of the second wafer seat 2 and corresponds to an area where the second arc-shaped concave surface 21 is located, and the second acting surface 22 is shaped like a right half of Y. A central angle of the second arc-shaped concave surface 21 is 30°-180°, preferably 90°-180°.

The first acting surface 12 and the second acting surface 22 work together to support a wafer 3 vertically.

In this embodiment, an outer edge of the wafer 3 is provided with a notch 31, the notch 31 is formed by horizontally cutting the edge of the wafer 3, that is, the notch 31 has a flat, and the width of the flat of the notch 31 is 55-60 mm.

In this embodiment, the cross-section of the first wafer seat 1 and the cross-section of the second wafer seat 2 are both trapezoidal structures with a big top and a small bottom. Of course, in other embodiments, the cross-section of the first wafer seat 1 and the cross-section of the second wafer seat 2 may be square structures or other structures.

As shown in FIG. 4, the first acting surface 12 is in line contact with the wafer 3 and the second acting surface 22 is in surface contact with the wafer 3 to support the wafer 3 vertically.

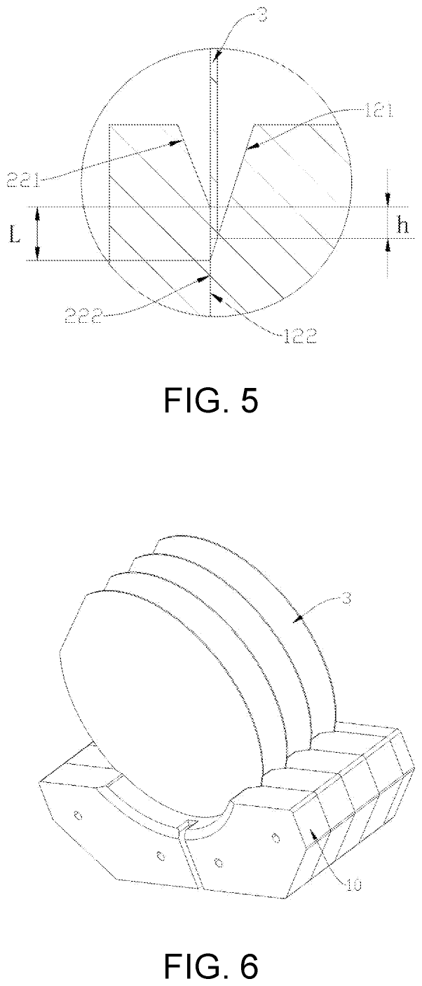

More specifically, as shown in FIG. 5, the first acting surface 12 comprises a first inclined surface 121 and a first vertical surface 122, and the second acting surface 22 comprises a second inclined surface 221 and a second vertical surface 222; and the first vertical surface 122 and the second vertical surface 222 are vertically mismatched and in contact with each other, that is, the top end of the first vertical surface 122 is not flush with the top end of the second vertical surface 222. In this case, the first inclined surface 121 is in line contact with the wafer 3, and more specifically, the first inclined surface 121 is in contact with a ridge between the front side and the lateral side of the wafer 3; the second vertical surface 222 mismatched with the first vertical surface 122 is in surface contact with the wafer 3, that is, one part of the second vertical surface 222 is exactly attached to the first vertical surface 122, and the other part (part L in FIG. 5) of the second vertical surface 22 is higher than the first vertical surface 122 and is attached to the edge of the back side of the wafer 3 to realize surface contact. In this way, the front side of the wafer 3 is completely prevented against contact with the base unit 10, thus guaranteeing the performance of the wafer 3 to the maximum extent.

The first vertical surface 122 and the second vertical surface 222 may be vertical flat surfaces or vertical wavy surfaces rather than being definitely flat surfaces, and may be any vertical surfaces as long as they can be in contact with the wafer 3 to support the wafer 3.

The width of the back side, attached to and in surface contact with the second vertical surface 222, of the wafer 3 is h, the radius of the wafer 3 is defined as R, and the ratio of h to R is 0.01-1, preferably 0.01-0.06. The ratio of h to L is greater than 0 and less than or equal to 1. In this way, the surface of the wafer will not be scratched, the space is saved, and the wafer can be placed more firmly, thus reducing the possibility of wafer breakage.

As shown in FIG. 6, the standing wafer holder may comprise multiple base units 1, the second wafer seat 2 and the first wafer seat 1 of every two adjacent base units 10 are integrated, that is to say, the first acting surface 12 and the second acting surface 22 are arranged on two sides of the first wafer seat 1 and also arranged on two sides of the second wafer seat 2.

In the above structure, the first wafer seat 1 and the second wafer seat 2 are separated. Of course, in other embodiments, the first wafer seat 1 and the second wafer seat 2 may be configured as an integrated structure, that is, the first arc-shaped concave surface 11, the second arc-shaped concave surface 21, the second acting surface 22 and the first inclined surface 121 are directly formed on the top surface of the base unit 10.

In this embodiment, the first arc-shaped concave surface 11 and the second arc-shaped concave surface 21 are continuous surfaces. Of course, in other embodiments, the first arc-shaped concave surface 11 and the second arc-shaped concave surface 21 may be discontinuous surfaces, and in this case, multiple first arc-shaped concave surfaces 11 and multiple second arc-shaped concave surfaces 21 are arranged, that is, multiple first acting surfaces 12 and multiple second acting surfaces 22 are arranged.

### Embodiment 2

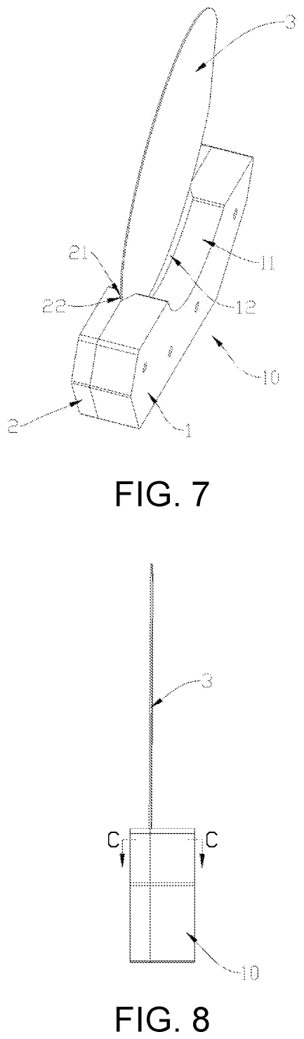

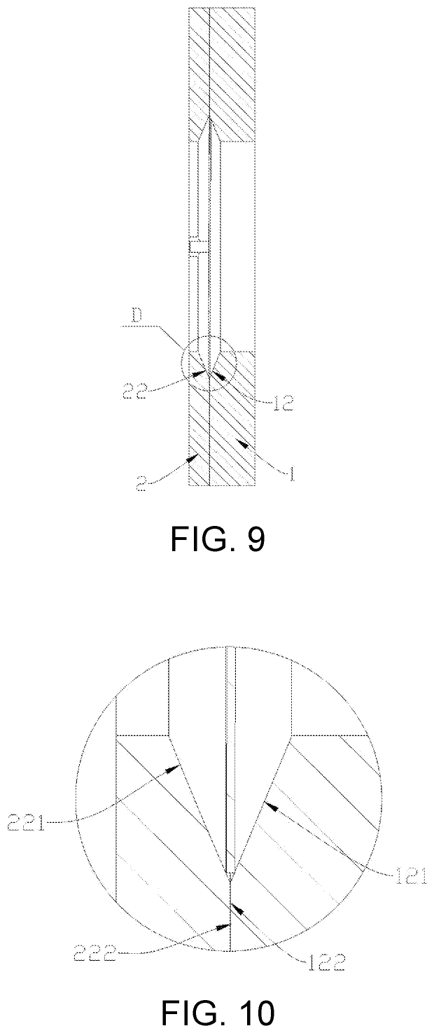

As shown in FIG. 7-FIG. 10, this embodiment is different from Embodiment 1 in that the first acting surface 12 is in line contact with the wafer 3 and the second acting surface 22 is in line contact with the wafer 3 to support the wafer 3 vertically.

More specifically, as shown inn FIG. 10, the first acting surface 12 comprises a first inclined surface 121 and a first vertical surface 122, and the second acting surface 22 comprises a second inclined surface 221 and a second vertical surface 222; the first vertical surface 122 and the second vertical surface 222 are in contact and completely matched with each other, that is, the top end of the first vertical surface 122 is flush with the top end of the second vertical surface 222, and the first acting surface 12 and the second acting surface 22 are assembled together to form a Y shape. In this case, the first inclined surface 121 is in line contact with the wafer 3, more specifically, the first inclined surface 121 is in contact with a ridge between the front side and the lateral side of the wafer 3; the second inclined surface 221 is in line contact with the wafer 3, and more specifically, the second inclined surface 221 is in contact with a ridge between the back side and the lateral side of the wafer 3. In this way, the front side and the back side of the wafer 3 will not be in contact with the base unit 10, thus guaranteeing the performance of the wafer to the maximum extent.

The first inclined surface 121 and the second inclined surface 221 are configured as V-shaped structures which are open upward, such that the wafer 3 can be placed in the first inclined surface 121 and the second inclined surface 221 easily. The inclination angle of the first inclined surface 121 and the inclination angle of the second inclined surface 221 are about 30°.

### Embodiment 3

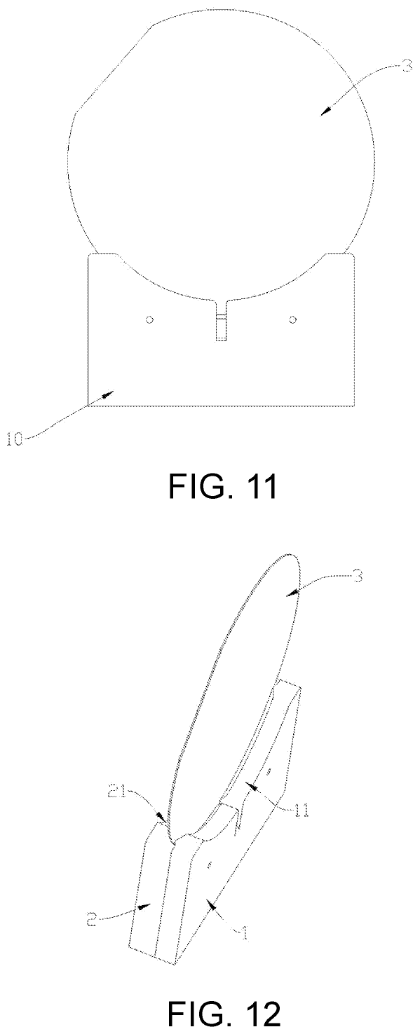

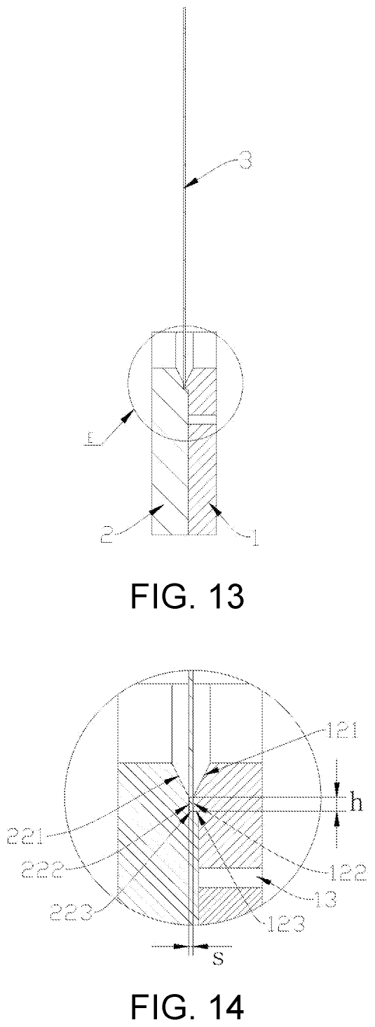

As shown in FIG. 11-FIG. 14, this embodiment is different from Embodiment 1 in that the first acting surface 12 is in surface contact with the wafer 3 and the second acting surface 22 is in surface contact with the wafer 3 to support the wafer 3 vertically.

More specifically, as shown in FIG. 14, the first acting surface 12 comprises a first inclined surface 121 and a first vertical surface 122, and the second acting surface 22 comprises a second inclined surface 221 and a second vertical surface 222; and the first vertical surface 122 is opposite to the second vertical surface 222 and is not in contact with the second vertical surface 222. Here the first vertical surface 122 may be opposite to the second vertical surface 222 completely or in a mismatched manner. That is to say, the first acting surface 12 and the second acting surface 22 form Y-shaped structures which are spaced from each other by a distance.

The first vertical surface 122 and the second vertical surface 222 are respectively in contact with outer edges of the front and back sides of the wafer 3. The width of the wafer 3 attached to and in surface contact with the first vertical surface 122 and the second vertical surface 222 is h, the radius of the wafer 3 is defined as R, the ratio of h to R is 0.01-1, and h in FIG. 14 is less than 3 mm.

The distance between the first vertical surface 122 and the second vertical surface 222 are adjustable to adapt to wafers with different thicknesses or to adapt to wafer processing errors. A support surface 223 perpendicular to the first vertical surface 122 or the second vertical surface 222 is formed at the bottom of the first vertical surface 122 or at the bottom of the second vertical surface 222. For example, in this embodiment, the support surface 223 is formed at the bottom of the second vertical surface 222 and extends towards the first vertical surface 122, a step surface 123 is formed at the bottom of the second vertical surface 222, the step surface 123 is erected on the support surface 223 and horizontally movable along the support surface 223 to adjust the distance between the first vertical surface 122 and the second vertical surface 222, that is, the distance S in FIG. 14 is adjustable, and S=0.5-2 mm, preferably S=0.6-1.6 mm.

A threaded hole 13 is formed in the first wafer seat 1, and after the distance between the first vertical surface 122 and the second vertical surface 223 is adjusted, a jackscrew is screwed into the threaded hole 13 to press against the second wafer seat 2, such that the distance between the first wafer seat 1 and the second wafer seat 2 is fixed.

### Embodiment 4

Different from Embodiments 1, 2 and 3 where the first acting surface 12 and the second acting surface 22 on the wafer holder are identical in structure, in this embodiment, the above three structures are combined, that is, multiple first arc-shaped concave surfaces 11 and multiple second arc-shaped concave surfaces 21 are arranged; in this case, the above three structures may be all applied to the same wafer holder, and the first arc-shaped concave surface 11 and the adjacent second arc-shaped concave surface 21 may be provided with the first acting surface 12 and the second acting surface 22 which are different in structure. The radian of the first arc-shaped concave surface 11 and the radian of the second arc-shaped concave surface 21 may be identical or different.

The above specific embodiments are used for explaining the invention rather than limiting the invention, and any modifications and variations made to the invention based on the spirit of the invention and within the protection scope of the claims should also fall within the protection scope of the invention.

1. A standing wafer holder, comprising:
at least one base unit, wherein:
the base unit comprises a first wafer seat and a second wafer seat;
a top of the first wafer seat is provided with a first arc-shaped concave surface, a first acting surface is formed on a side, facing the second wafer seat, of the first wafer seat and corresponds to an area where the first arc-shaped concave surface is located, and the first acting surface is shaped like a left half of Y;
a top of the second wafer seat is provided with a second arc-shaped concave surface, a second acting surface is formed on a side, facing the first wafer seat, of the second wafer seat and corresponds to an area where the second arc-shaped concave surface is located, and the second acting surface is shaped like a right half of Y;
the first acting surface and the second acting surface work together to support a wafer vertically.

2. The standing wafer holder according to claim 1, wherein the first acting surface is in line contact with the wafer and the second acting surface is in line contact with the wafer to support the wafer vertically;
or, the first acting surface is in line contact with the wafer and the second acting surface is in surface contact with the wafer to support the wafer vertically;
or, the first acting surface is in surface contact with the wafer and the second acting surface is in surface contact with the wafer to support the wafer vertically.

3. The standing wafer holder according to claim 1, characterized in that, wherein the first acting surface comprises a first inclined surface and a first vertical surface, and the second acting surface comprises a second inclined surface and a second vertical surface; and the first vertical surface and the second vertical surface are matched and in contact with each other, and the first inclined surface and the second vertical surface are respectively in line contact with the wafer.

4. The standing wafer holder according to claim 1, wherein the first acting surface comprises a first inclined surface and a first vertical surface, and the second acting surface comprises a second inclined surface and a second vertical surface; the first vertical surface and the second vertical surface are vertically mismatched and in contact with each other; the first inclined surface is in line contact with the wafer, and the second vertical surface mismatched with the first vertical surface is in surface contact with the wafer; or, the second inclined surface is in line contact with the wafer, and the first vertical surface mismatched with the second vertical surface is in surface contact with the wafer.

5. The standing wafer holder according to claim 1, wherein the first acting surface comprises a first inclined surface and a first vertical surface, and the second acting surface comprises a second inclined surface and a second vertical surface; and the first vertical surface and the second vertical surface are respectively in contact with outer edges of two sides of the wafer.

6. The standing wafer holder according to claim 5, wherein a support surface (223) perpendicular to the first vertical surface or the second vertical surface is formed at a bottom of the first vertical surface or at a bottom of the second vertical surface, a step surface is formed at the bottom of the second vertical surface or at the bottom of the first vertical surface, the step surface is erected on the support surface (223) and is horizontally movable along the support surface (223) to adjust a distance between the first vertical surface and the second vertical surface, and the distance is 0.5-2 mm.

7. The standing wafer holder according to claim 4, wherein a surface contact width of the wafer with the first vertical surface or/and the second vertical surface is h, a radius of the wafer is R, and the ratio of h to R is 0.01-1.

8. The standing wafer holder according to claim 1, wherein a central angle of the first arc-shaped concave surface or/and the second arc-shaped concave surface is 30°-180°.

9. The standing wafer holder according to claim 1, wherein multiple said base units (10), wherein the second wafer seat and the first wafer seat of every two adjacent said base units (10) are integrated.

10. The standing wafer holder according to claim 1, wherein the first wafer seat and the second wafer seat are configured as an integrated structure.

11. The standing wafer holder according to claim 1, wherein the first arc-shaped concave surface and/or the second arc-shaped concave surface are continuous or discontinuous, and the first acting surface and/or the second acting surface are identical or different in structure.

12. The standing wafer holder according to claim 5, wherein a surface contact width of the wafer with the first vertical surface or/and the second vertical surface is h, a radius of the wafer is R, and the ratio of h to R is 0.01-1.
